(19) United States
(12) Patent Application Publication
(10) Pub. No.: US 2019/0139790 A1
(43) Pub. Date: May 9, 2019

(54) DISPENSING ARM HEAD HAVING POINT OF DISPENSE RECIRCULATION MODE

(71) Applicant: VEECO PRECISION SURFACE PROCESSING LLC, Horsham, PA (US)

(72) Inventors: Paul Vit, Horsham, PA (US); William Gilbert Breingan, Media, PA (US); Christopher Hofmeister, Hampstead, NH (US)

(21) Appl. No.: 16/178,934

(22) Filed: Nov. 2, 2018

Related U.S. Application Data
(60) Provisional application No. 62/582,679, filed on Nov. 7, 2017.

(51) Int. Cl. H01L 21/67

(52) U.S. Cl. CPC H01L 21/6715; B05C 5/027; H01L 21/67051

(57) ABSTRACT

A dispense arm device for controllably discharging a fluid onto a substrate includes a dispense head coupled to and contained within an arm portion of the dispense arm device, wherein the dispense head having a valve assembly that is configured to operate in: (1) a recirculation mode in which a dispense outlet formed in the dispense head is closed off and a recirculation path is opened for allowing heated chemistry that is delivered to the dispense head to be delivered back from the dispense head to a remote location (e.g., a recycle tank); and (2) a dispense mode in which the dispense outlet is opened to allow heated chemistry to be discharged from the dispense head and the recirculation path is closed off.

### CROSS REFERENCE TO RELATED APPLICATION

The present application claims priority to and the benefit of U.S. patent application Ser. No. 62/582,679, filed Nov. 7, 2017, which is hereby incorporated by reference in its entirety.

### TECHNICAL FIELD

The present invention relates to wafer processing equipment and more particularly, relates to a head for a dispensing arm that has both a point of dispense recirculation mode and a dispense mode and is constructed to minimize variation in the temperature of the chemistry deposited onto the wafer during processing.

### BACKGROUND

In wafer processing equipment, tight process control is of paramount importance. Therefore, it is desirable to minimize variation in the temperature of chemistry deposited onto the wafer during processing.

### SUMMARY

In accordance with one embodiment, the present invention provides a dispense arm for controllably discharging a fluid. The dispense arm includes a dispense head contained within an arm structure. The dispense head has a valve assembly that is configured to operate in: (1) a recirculation mode in which a dispense outlet is closed off and a recirculation path is opened for allowing heated chemistry that is delivered to the dispense head to be delivered back to a chemical supply location; and (2) a dispense mode in which the dispense outlet is opened to allow heated chemistry to be discharged from the dispense arm and the recirculation path is closed off.

The present invention minimizes variation in the temperature of chemistry deposited onto the wafer during processing by allowing for a continuous flow of chemistry through the dispense arm whether the arm is actively dispensing or not. Additionally, a thermocouple is built in near the point of dispense to allow accurate monitoring of the temperature of the chemistry. Advantages of this design include that there are no moving seals to wear or fail and all surfaces that touch chemistry can be made from chemically compatible fluoropolymers (e.g. Teflon).

### BRIEF DESCRIPTION OF THE DRAWING FIGURES

FIG. 1 is a top and side perspective view of a dispense arm in accordance with one exemplary embodiment of the present invention;

FIG. 2 is a top and side perspective view of a dispense head for use in the dispense arm of the FIG. 1;

FIG. 3 is a side elevation view of the dispense head;

FIG. 4 is a front elevation view of the dispense head;

FIG. 5 is a rear elevation view of the dispense head;

FIG. 6 is a cross-sectional view taken along the line A-A of FIG. 4 illustrating a recirculation mode of operation;

FIG. 7 is a cross-sectional view taken along the line B-B of FIG. 4 illustrating the recirculation mode of operation;

FIG. 8 is a cross-sectional view taken along the line C-C of FIG. 4 illustrating the recirculation mode of operation;

FIG. 9 is a cross-sectional view taken along the line D-D of FIG. 4 illustrating the recirculation mode of operation;

FIG. 10 is a cross-sectional view taken along the line E-E of FIG. 4 illustrating the recirculation mode of operation;

FIG. 11 is a cross-sectional view taken along the line A-A of FIG. 4 illustrating a dispense mode of operation;

FIG. 12 is a cross-sectional view taken along the line B-B of FIG. 4 illustrating the dispense mode of operation;

FIG. 13 is a cross-sectional view taken along the line C-C of FIG. 4 illustrating the dispense mode of operation;

FIG. 14 is a cross-sectional view taken along the line D-D of FIG. 4 illustrating the dispense mode of operation;

FIG. 15 is a cross-sectional view taken along the line E-E of FIG. 4 illustrating the dispense mode of operation;

FIG. 16A is a front elevation view of a dispense head having an alternative seat design;

FIG. 16B is a cross-sectional view taken along the line F-F of FIG. 16A;

FIG. 17A is a front elevation view of a dispense head having another alternative seat design;

FIG. 17B is a cross-sectional view taken along the line G-G of FIG. 17A;

FIG. 18A is a front elevation view of a dispense head having another alternative seat design; and

FIG. 18B is a cross-sectional view taken along the line H-H of FIG. 18A.

### DETAILED DESCRIPTION OF CERTAIN EMBODIMENTS

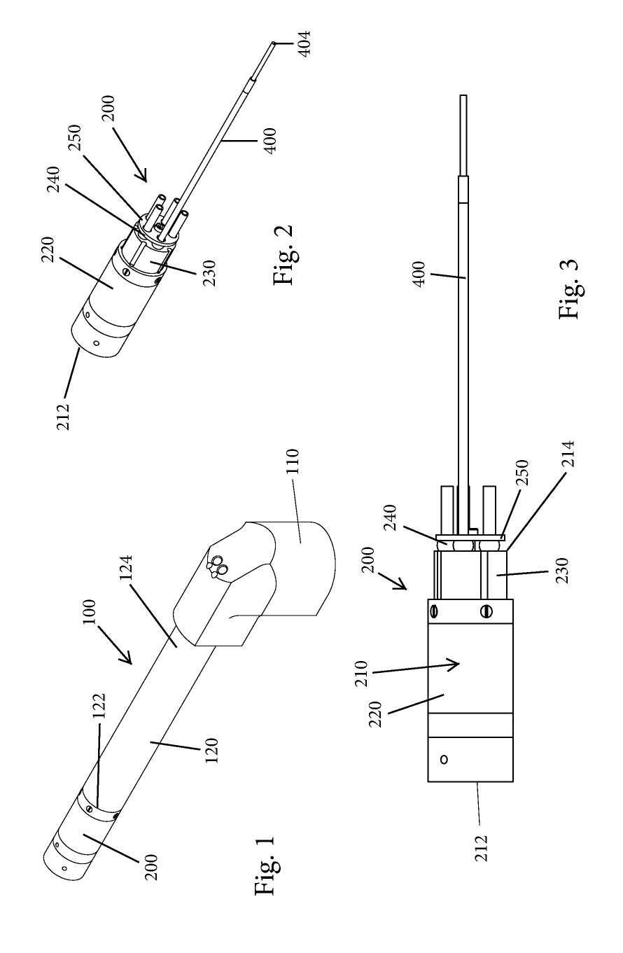

FIG. 1 illustrates a dispense arm 100 that is part of a wafer processing system. As will be understood by one of skill in the art, a wafer processing system includes equipment that is used to process the substrate to form a completed product, such as an integrated circuit wafer, which is typically in the form of flat round disks (although other shapes are possible) and often is made from silicon. A wafer processing system is thus configured to process the wafer using various chemicals. One process is the use of liquid chemical etchant to remove material from or on the substrate, this process is often referred to as wet etching. Commonly used methods include dispensing fluid on a wafer while spinning (referred to as “single wafer processing”). As wafer sizes increase and geometry sizes decrease, substantial benefits can be realized by employing single wafer processing inasmuch as the processing environment may be better controlled. The dispense arm 100 is thus the component that is configured to controllably dispense the fluid (chemistry (etchant)) onto the spinning wafer which is located below. The dispense arm 100 is operatively connected to an automated control system which is designed to controllably move the dispense arm 100 relative to the wafer's top surface so as to permit controlled dispensing of the chemical etchant at a desired location. Since the water is rotating, etchant that is dispensed at a single radial location results in a ring-shaped etch along the wafer's surface at the single radial location (i.e., at a given radius from the center).

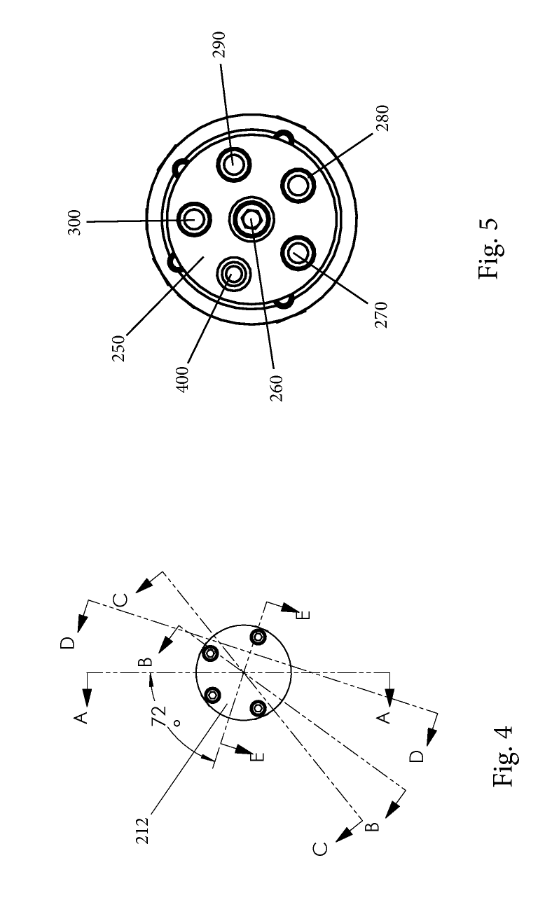

As shown, the dispense arm 100 has a housing that can be constructed so as to include a base portion 110 and an arm portion 120. The arm portion 120 extends radially outward from the base portion 110 and includes a distal portion 122 and a proximal portion 124 that is connected to the base portion 110. In the illustrated embodiment, the arm portion 120 has a cylindrical shape; however, other shapes are equally possible. The arm portion 120 is also a hollow structure and is intended to receive a dispense head 200 that is illustrated in detail in FIGS. 2-5.

The dispense head 200 is configured to be received within the hollow interior of the dispense arm 120. As shown in FIG. 1, the dispense head 200 extends distally beyond the distal portion 122 of the arm portion 120. The finish/fit between the dispense head 200 and arm portion 120 is preferably clean and therefore, the dispense head 200 can have a cylindrical shape.

More particularly, the dispense head 200 includes a body 210 that has a first end 212 and an opposing second end 214. The first end 212 of the body 210 defines the distal end of the dispense arm 100. The body 210 has a first portion 220 that terminates in the first end 212 and a second portion 230 that is of reduced dimensions (e.g., diameter) relative to the first portion 220. As illustrated, both the first portion 220 and the second portion 230 can have a cylindrical shape with an annular shaped shoulder being formed between the first portion 220 and the second portion 230. As shown, adjacent the exposed free end of the second portion 230, a ferrule 240 is provided. As understood, the ferrule 240 is a ring or cap. A clamp plate 250 is disposed adjacent the ferrule 240 and thus, the ferrule 240 serves to space the clamp plate 250 from the second portion 230. The clamp plate 250 includes a number of holes formed therein as described below for allowing passage of other parts (e.g., conduits) and also to allow coupling of the clamp plate 250 to the second portion 230 as by a fastener 260, such as a screw or bolt, etc.

As shown in FIGS. 2-5, a number of conduits (e.g., tubes) pass through the holes of the clamp plate 250 in a direction away from the second portion 230. For example, a first conduit 270, a second conduit 280, a third conduit 290, and a fourth conduit 300 are provided. The conduits can be in the form of tubes, etc. In the illustrated embodiment, the first conduit 270 comprises a fluid inlet conduit for delivering the chemistry (e.g., etchant) to the dispense head 200 and thus, the first conduit 270 can be thought of as being a chemical supply conduit. The second conduit 280 comprises a recirculation conduit that is intended to carry recirculated chemistry away from the dispense head 200 for recirculation thereof as described below. The third conduit 290 is a fluid inlet which can be in the form a compressed gas (air) conduit that is configured to deliver a fluid (e.g., compressed air) to the dispense head 200. The fourth conduit 300 is another fluid conduit and can be in the form of a vacuum or suck back conduit for withdrawing fluid (chemistry) from the dispense head 200. The first conduit 270, second conduit 280, third conduit 290 and fourth conduit 300 are circumferentially spaced apart from one another.

A thermocouple 400 is also provided and as described herein is used to monitor the temperature of the chemistry within the dispense head 200. As is known, a thermocouple 400 is an electrical device consisting of two dissimilar electrical conductors forming electrical junctions at differing temperatures. A thermocouple produces a temperature-dependent voltage as a result of the thermoelectric effect, and this voltage can be interpreted to measure temperature. The thermocouple 400 is an elongated structure that has a first end 402 that is disposed internally within the dispense head 200 in contact with the flow of the chemistry as described below. An opposite second end 404 of the dispense head 200 is located outside of the dispense head 200. Like the conduits 270, 280, 290, 300, the thermocouple 400 extends outwardly in a direction away from the second portion 230. The length of the thermocouple 400 can be greater than the lengths of the conduits 270, 280, 290, 300.

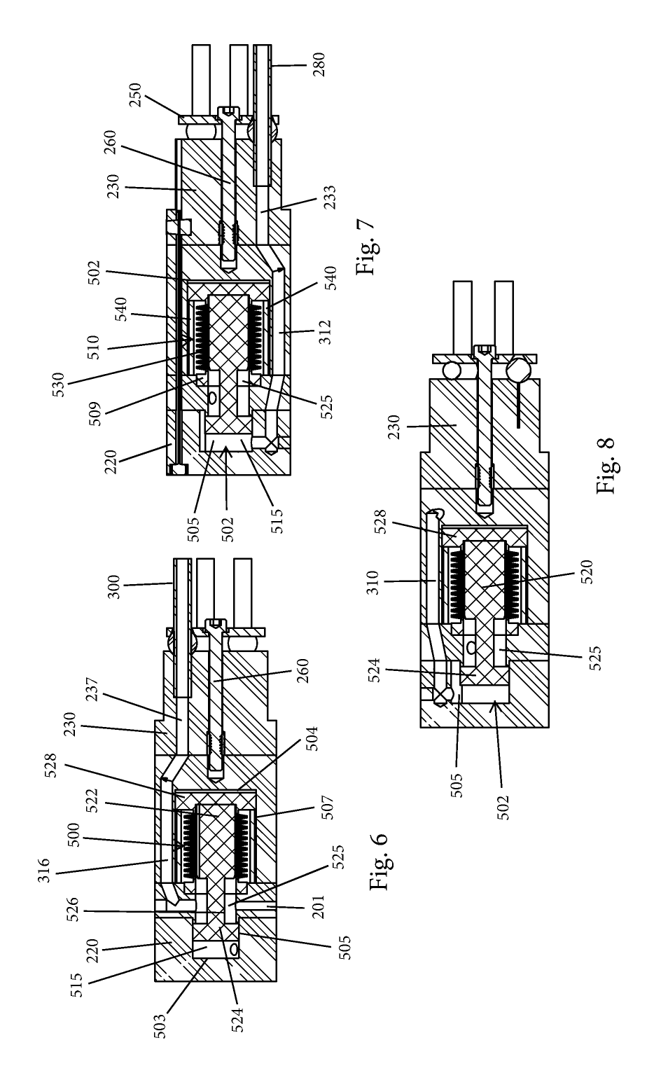

The thermocouple 400 is also circumferentially spaced relative to the conduits. As shown, the conduits 270, 280, 290, 300 and the thermocouple 400 are disposed about (radially from) a center of the second portion 230 and the clamp plate 250. The conduits and the thermocouple can be spaced equidistant. The fastener 260 is centrally located within the second portion 230 and the clamp plate 250. As shown in FIG. 6, the fastener 260 can serve to attach the second portion 230 to the first portion 220 in that the fastener 260 passes completely through the second portion 230 into the first portion 220.

In accordance with the present invention, the dispense head 200 is constructed so that it can be operated in at least two operating modes, namely, a recirculation mode and a dispense mode. The dispense head 200 is constructed such that it allows for a continuous flow of chemistry through the dispensed arm 100 whether the dispense arm 100 is actively dispensing chemical or not. As describe below, the thermocouple 400 is built in near a point of dispense to allow accurate monitoring of the temperature of the chemistry (liquid). Advantages of this design include that there are no moving seals to wear or fail and all surfaces that touch chemistry can be made from chemically compatible fluoropolymers (e.g. Teflon) or other suitable materials.

In the recirculation mode of operation, heated chemistry enters the dispensing head 200 and is not dispensed through a dispensing outlet 201 but is recirculated back to the chemistry supply, thereby allowing it to be recycled. In the dispense mode of operation, the heated chemistry is routed to the dispensing outlet 201.

As shown in FIGS. 6-10, the second portion 230 comprises a channeled body in that channels or passageways are formed to both receive ends of the conduits 270, 280, 290, 300 and thermocouple 400. Thus, for each of the conduits 270, 280, 290, 300 and the thermocouple 400, there is a corresponding channel or passageway formed in and through the second portion 230. The channels are sized so that the ends of the conduits 270, 280, 290, 300 and thermocouple 400 can be received and contained and held within the respective channels/passageways. This allows fluid to flow through the conduit and into or out of the respective channel formed in the second portion 230.

In the illustrated embodiment, the second portion 230 thus includes a first passageway 231 that receives the first conduit 270; a second passageway 233 that receives the second conduit 280; a third passageway 235 that receives the third conduit 290; and a fourth passageway 237 that receives the fourth conduit 300. The fastener 260 passes through a center passageway. In one embodiment, each of the passageways 231, 233, 235 and 237 are linear in shape.

The first portion 220 is designed so as to be complementary to and be in fluid communication with the passageways 231, 233, 235 and 237 formed in the second portion 230. Therefore, the first portion 220 comprises a channeled body and further includes a valve assembly 500 that is movably contained therein. As described herein, the valve assembly 500 can be thought of as being a three-way valve.

As shown, the valve assembly 500 can be centrally located within the first portion 220 and includes a valve cavity (space or inner compartment) 502 that is formed within the first portion 220. The valve cavity 502 has a first end 503 and an opposing second end 504. As shown, the dimensions of the valve cavity 502 can vary along its length and in particular, the first end 503 can have smaller dimensions than the second end 504. A right-angle shoulder can be formed between two different defined sections of the valve cavity and in particular, the valve cavity 502 can include a first section 505 that terminates in the first end 503 and a second section 507 that terminates in the second end 504.

The valve assembly 500 also includes a movable valve 510 that can be positioned in an extended position and a retracted position as described herein. The valve 510 comprises a plunger 520 that has a main body portion 522 and a forward flange portion 524 at one end thereof and a rear flange portion 528 at another end thereof. Between the forward flange portion 524 and the main body 522 is a shaft portion 526 that has dimensions smaller than the forward flange portion 524 and main body 522. For example, a diameter of the forward flange portion 524 and a diameter of the main body 522 can be the same, while the shaft portion 526 has a smaller diameter. The rear flange portion 528 can have a diameter that is greater than the main body 522. The rear flange portion 528 is sized only for reception and travel within the second section 507. There is an annular space 525 formed about the shaft portion 526 due to the reduced diameter of the shaft portion 526.

The valve assembly 500 further includes a bellows 530 that is disposed circumferentially about the main body portion 522 and a return spring 540 that is also disposed about the main body portion 522 (radially outward from the bellows 530). The bellows 530 and return spring 540 are also sized only for reception and travel within the second section 507. The bellows 530 and return spring 540 are disposed adjacent the rear flange portion 528 and thus act thereon when a return biasing force is generated as discussed below. As shown, at the forward end of the second section 507 is a stop 509 that limits the degree of travel of the bellows 530 and return spring 540 when the valve 510 moves in a forward direction. As described herein, when the valve 510 is moved forward, the bellows 530 and return spring 540 contact the stop 509 (which can be thought of as being a shoulder between the first section 505 and second section 507) and become compressed, thereby storing energy. In this condition, the bellows 530 and return spring 540 are compressed between the stop 509 and the rear flange portion 528. When the driving force is removed from the plunger 520, the stored energy is released and the plunger 520 is driven rearward as described herein.

As mentioned herein, the first portion 220 of the dispense head 200 is channeled and in particular, there are channels/passageways that are in fluid communication with the channels/passageways formed in the second portion 230 and the valve cavity 502. More specifically, the first portion 220 includes a first channel/passageway 310 that is in fluid communication with the first passageway 231 and the first conduit 270 and also is in fluid communication with the valve cavity 502. The first portion 220 includes a second channel/passageway 312 that is in fluid communication with the second passageway 233 and the second conduit 280 and also is in selective fluid communication with the valve cavity 502. The first portion 220 includes a third channel/passageway 314 that is in fluid communication with the third passageway 235 and the third conduit 290 and also is in fluid communication with the valve cavity 502. The first portion 220 includes a fourth channel/passageway 316 that is in fluid communication with the fourth passageway 237 and the fourth conduit 300 and also is in fluid communication with the valve cavity 502.

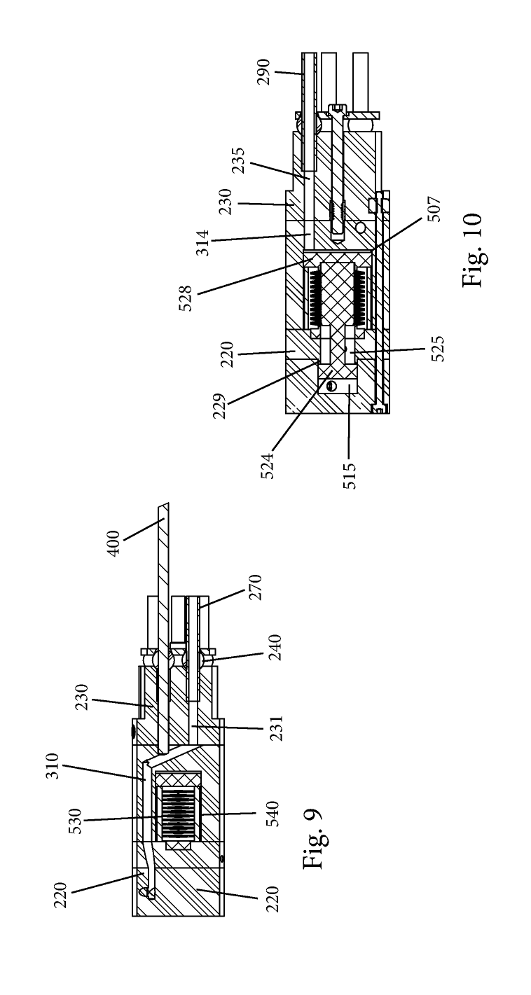

As shown in FIGS. 8 and 9, the first channel 310 can include an angled portion that leads to another portion that leads to the valve cavity 502 for carrying the heated chemistry to the valve cavity 502. Along the angled portion, one end of the thermocouple 400 is exposed and is in contact with the heated chemistry for measuring the temperature of the heated chemistry as it flows toward the valve cavity 502. As shown in FIG. 8, one end of the first channel 310 communicates with the forward end (first section 505) of the valve cavity 502.

The second channel 312 also communicates with the forward end (first section 505) of the valve cavity 502 as shown in FIG. 7 and as described below and will be appreciated in view of FIGS. 8 and 9, the liquid chemistry that is delivered to the forward end of the valve cavity 502 (forward of the valve 510) can flow into the second channel 312 and then into the second passageway 233 and ultimately the second conduit 280 which leads to the source of the chemistry, thereby allowing the reuse of the chemistry when the dispense head 200 is operating in recirculation mode.

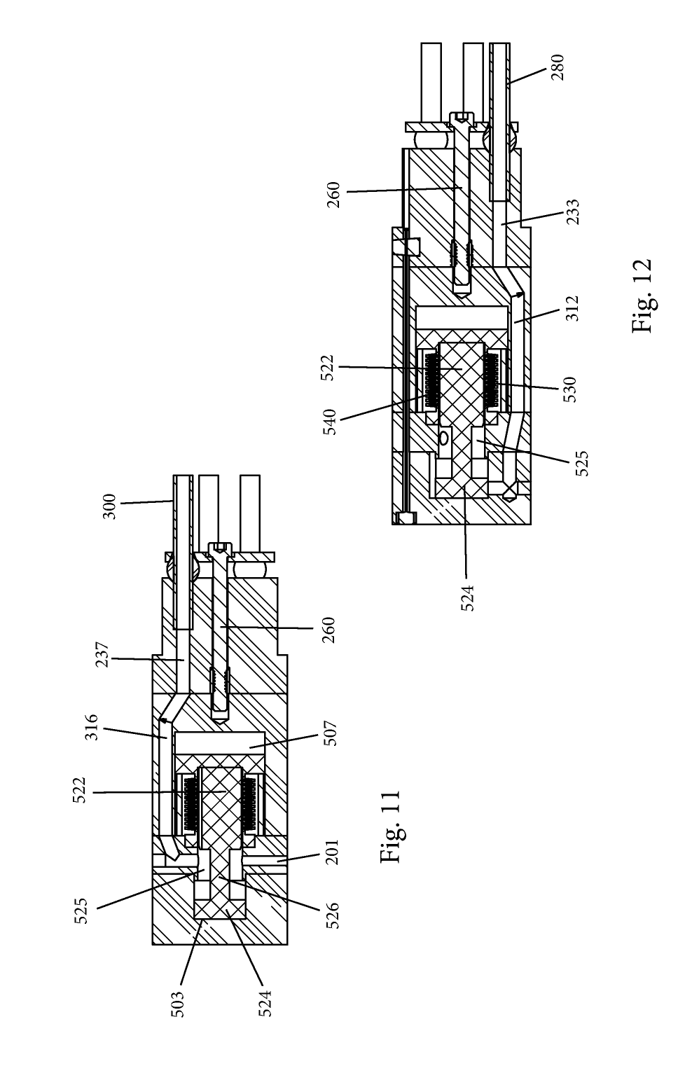

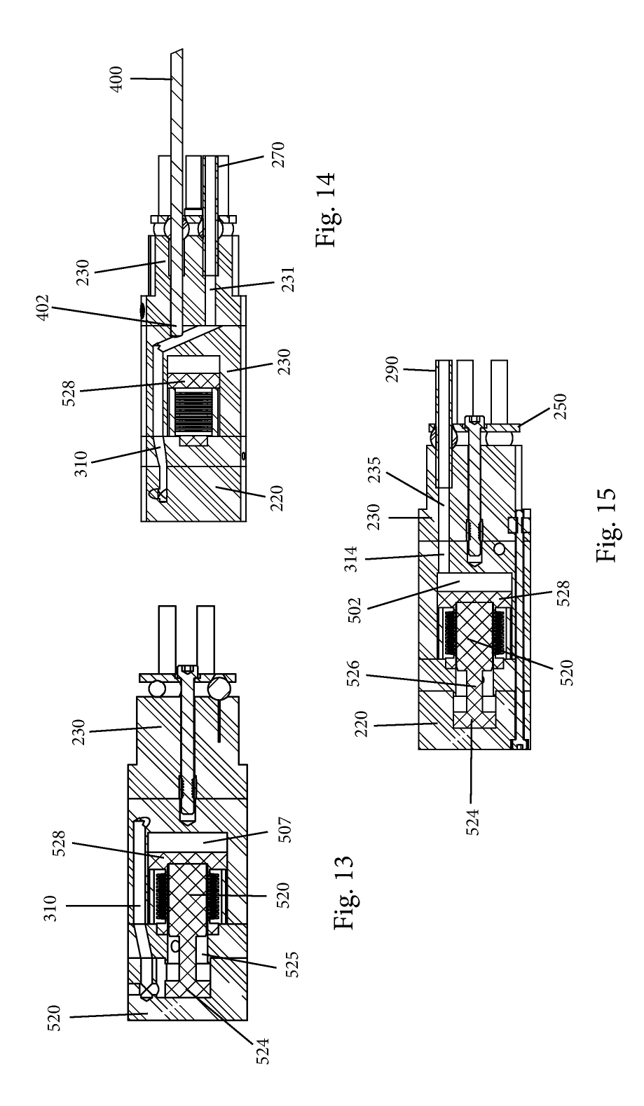

As shown in FIG. 10, the third channel 314 communicates with a rear end (second section 507) of the valve cavity 502 and more particularly, the third channel 314 opens into the valve cavity 502 to the rear of the rear flange portion 528. As a result, when the fluid travels within the third channel 314, the fluid directly contacts the rear flange portion 528 and causes movement of the valve 510 within the valve cavity 502. The fluid (e.g., compressed air) within the third channel 314 is therefore the driving force for causing the plunger 520 to move from the retracted (at rest) position (FIGS. 6-10) to the extended position (FIGS. 11-15). The force of the fluid within the third channel 314 is greater than the biasing force of the return spring 540 and therefore, the force of the fluid is able to exert a sufficient force against the rear flange portion 528 to cause forward movement of the plunger 520 within the valve cavity 502.

The fourth channel 316 communicates with the fourth conduit 300 with a forward end of the fourth channel 316 communicating with the valve cavity 502 as shown in FIG. 6. Unlike the first and second channels 310, 312 that communicate with the forward end of the valve cavity 502, the fourth channel 316 communicates with a dispensing portion of the valve cavity 502. The dispensing portion includes dispensing outlet (dispense port) 201 which discharges the chemistry (heated liquid) from the valve cavity 502. The dispensing outlet 201 is formed as a channel in the second portion 230 and extends radially outward from the valve cavity 502 and is open along the outer surface of the second portion 230. As shown, the dispensing outlet 201 is spaced from the first end (forward end) of the valve cavity 502. As described below in more detail, the fourth channel 316 is intended for selectively withdrawing any chemistry (liquid) that remains in the dispensing portion after dispensing action has been completed. The fourth conduit 300 is operatively connected to a suction source or similar equipment which can generate negative pressure within the fourth conduit 300, the fourth channel/passageway 316 and the fourth passageway 237.

As shown in FIG. 10, when the forward flange portion 524 is retracted, its degree of travel is limited by a wall 229 that can be considered to be a valve seat for the forward flange portion 524, whereby the spaces 515, 525 are sealed from one another.

As mentioned above, the dispense head 200 operates in a recirculating mode (FIGS. 6-10) and a dispense mode (FIGS. 11-15) each of which is discussed below.

Recirculation Mode FIGS. 6-10 illustrate the recirculation mode. In the recirculation mode, the valve 510 is located in the fully retracted position in which the rear flange portion 528 is proximate to or in contact with rear wall of the rear end of the valve cavity 502. When the valve 510 is in this position, the forward flange portion 524 is spaced from the first end 503 of the valve cavity 502 so as to define a forward space 515 that is located between the forward flange portion 524 and the first end of the valve cavity 502. In the recirculation mode, the chemical supply path (defined by the first conduit 270, the first channel/passageway 310, and the first passageway 231) delivers the chemistry (liquid) to the forward space 515 ahead of the forward flange portion 524. Since the recirculation path (defined by the second conduit 280, the second channel/passageway 312, and the second passageway 233) is also in fluid communication with the forward space 515, the heated chemistry delivered to the forward space 515 is routed to the recirculation path resulting in the delivered heated chemistry being recirculated when the dispense head 200 is in the recirculation mode which is a mode in which the chemistry is not dispensed from the dispense arm 100.

The dispense outlet 201 is thus closed in the recirculation mode. As shown in FIG. 6, the dispense outlet 201 communicates with the annular space 525 formed about the shaft portion 526 but does not communicate with the forward space 515 to which the heated chemistry is delivered and thus, the heated chemistry is not dispensed. Likewise, the suction pathway defined by the fourth conduit 300, the fourth channel/passageway 316 and the fourth passageway 237 is closed off since it communicates with the dispensing portion of the valve cavity 502 which again is placed offline due to the location of the plunger 520 within the valve cavity 502 (in the retracted position).

As the chemistry flows through the chemical supply line, it contacts the thermocouple 400 which allows for accurate temperature control. Outside of the dispense arm 100, the recirculation path flows into a receptacle, such as a tank, (chemical supply) that is, in turn, feed into the chemical supply line (conduit 270), allowing the chemistry to be recycled.

### Dispense Mode

In the dispense mode of operation, the chemistry (fluid) is discharged through the dispense outlet 201 while the recirculation path is closed off such that the heated chemistry is prevented from flowing within the recirculation path.

To switch the dispense head 200 from the recirculation mode to the dispense mode, fluid (e.g., compressed air or nitrogen) is blown in through the compressed air path resulting in the fluid contacting the rear flange portion 528 causing the plunger 520 to be driven forward. This driving action of the plunger 520 causes the compression of the bellows 530 and return spring 540 as the plunger 520 pushes forward. As the plunger 520 moves forward within the valve cavity 502, it opens the dispense path and covers up the opening to the recirculation path. A comparison of FIGS. 6-10 (recirculation) with FIGS. 11-15 (dispense) shows that in the dispense mode of operation, the chemical supply path is in fluid communication with the annular space 525 formed about the shaft portion 526 and the forward space 515 is eliminated. As shown in FIG. 11, in a dispensing mode, the dispense outlet 201 is in fluid communication with the annular space 525 and thus, when the heated chemistry flows into this annular space 525 from the chemical supply path, the heated chemistry flows into and through the discharge outlet (dispense point) 201. As shown in FIG. 12, the recirculation path is closed off by the elimination of the forward space 515 by placement of the forward flange portion at the first (front) end of the valve cavity 502 (which is where the entrance to the recirculation path is located).

This valve arrangement allows the fluid to continue flowing through the chemical supply path at the same temperature and flow rate, without interruption, thus maintaining steady process conditions. The only difference in the dispense mode of operation is that the flow is now directed through the dispense outlet 201 and onto the surface of the wafer being processed.

When the process is completed, releasing the gas pressure that compressed the bellows 530 and return spring 540 allows the return spring 540 to push the plunger 520 back to its previous location, closing off the flow to the dispense outlet 201 and opening the recirculation path again.

Additionally with reference to FIG. 11, the inclusion of the suck back path allows the chemistry stranded in the dispense point (the annular space 525 and the dispense outlet 201) to be sucked back through the dispense head 200, thus preventing dripping after the dispense is shut off. For example, negative pressure (a vacuum) can be supplied to the suck back path causing any chemistry that may remain within the annular space 525 or even within the dispense outlet 201) to be sucked through the suck back path (to a collection vessel). As mentioned, this prevents any chemistry from dripping.

It will be understood that the suck back path can be eliminated to allow a volume of fluid to be held in the valve cavity 502.

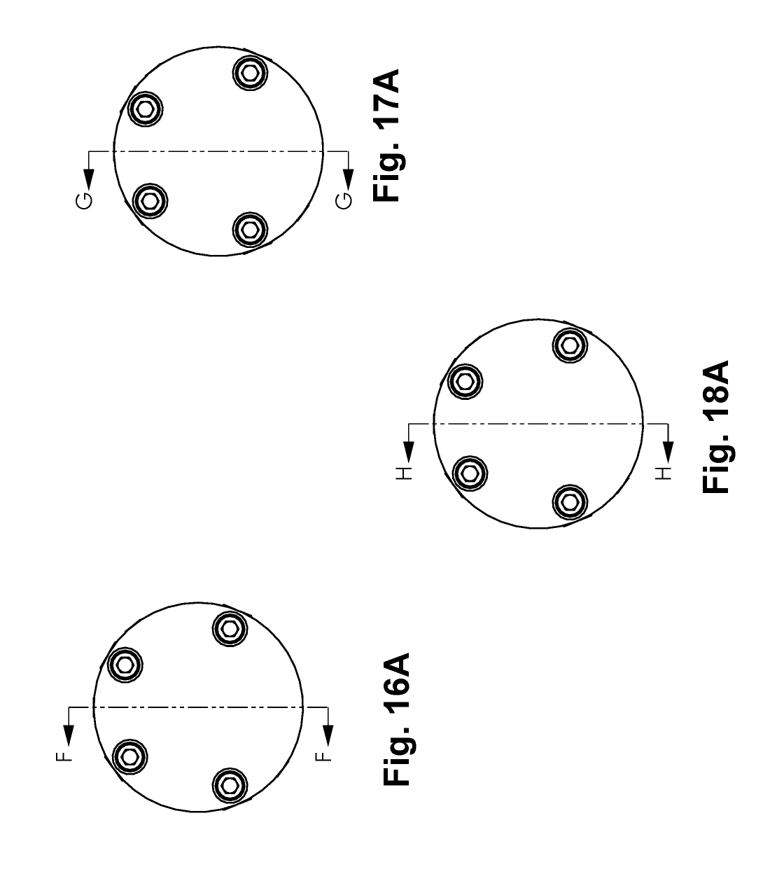

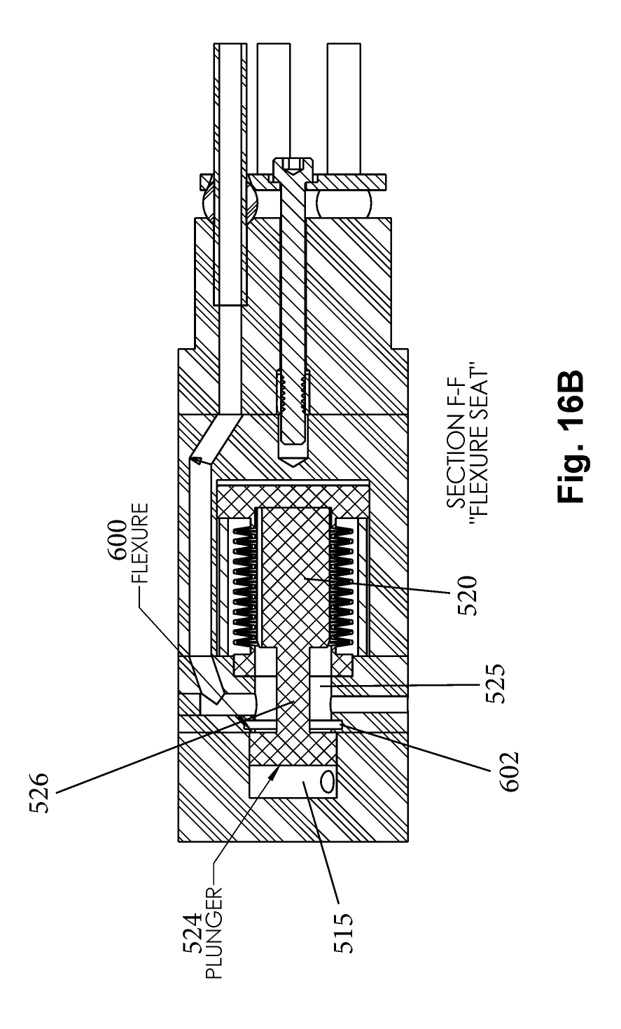

FIGS. 16A and 16B illustrate an alternative arrangement between the valve seat and the plunger. In particular, in FIG. 16B, a flexure seat 600 is provided and represents a flexible flange that is created by forming an annular shaped recess 602, thereby defining the flexure seat 600 about which the plunger 520 seats when in its retracted position. Unlike the surface to surface valve seat 229 of FIG. 10, the flexure seat 600 has a degree of flexibility that provides a sealing arrangement between the plunger 520 and the valve seat (flange 600).

The flange 600 can be formed of a suitable material that can flex, such as certain plastics, rubbers, etc.

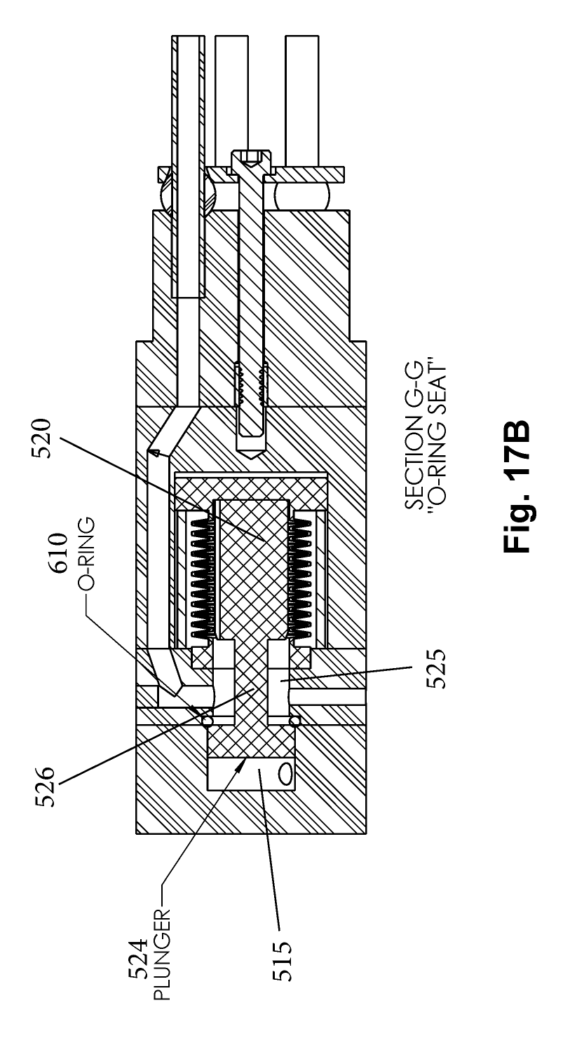

FIGS. 17A and 17B illustrate an alternative arrangement between the valve seat and the plunger. In particular, in FIG. 17B, an O-ring 610 is provided and disposed about the plunger 520 with the shaft portion 526 of the plunger 520 passing therethrough. The O-ring 610 can be anchored into the body 210 of the dispense head 200 (e.g., by being provided on a ledge as shown) proximate the dispensing outlet 201. The O-ring 610 thus provides a sealing arrangement between the plunger 520 since the plunger 520 seats against the O-ring 610 in its retracted position. Unlike FIG. 10 arrangement in which the plunger and valve seat sealing arrangement is a surface-to-surface arrangement, in FIG. 17B, the plunger 520 seats against the O-ring 610 to provide improved sealing (to prevent any leakage between spaces 515, 525).

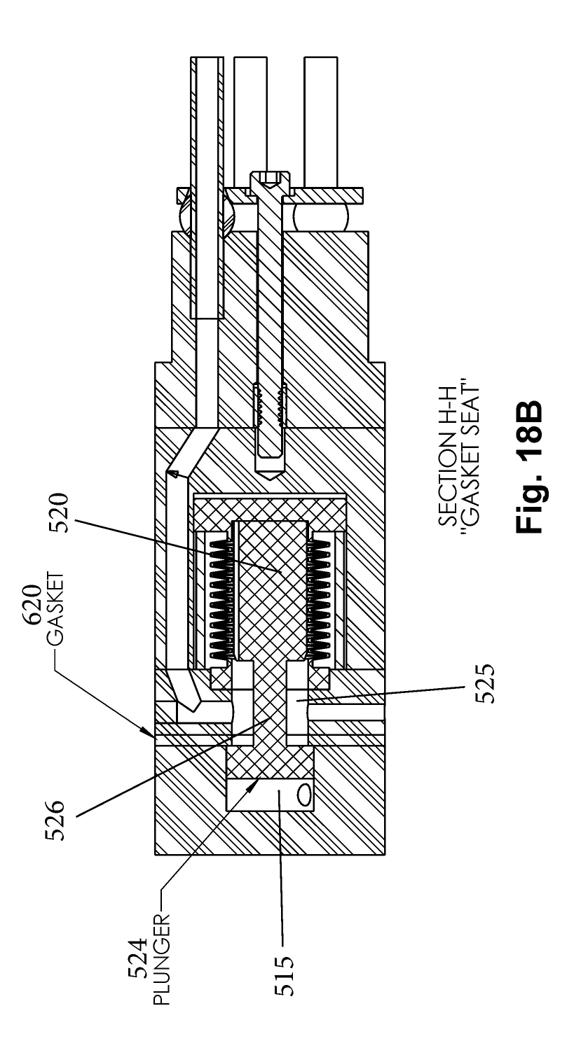

FIGS. 18A and 18B illustrate an alternative arrangement between the valve seat and the plunger 520. In particular, in FIG. 18B, a gasket 620 is provided and disposed about the plunger 520 with the shaft portion 526 of the plunger 520 passing therethrough. The gasket 620 thus provides a sealing arrangement between the plunger 520 since the plunger 520 seats against the gasket 620 in its retracted position. Unlike FIG. 10 arrangement in which the plunger and valve seat sealing arrangement is a surface-to-surface arrangement, in FIG. 18B, the plunger 520 seats against the gasket 620 to provide improved sealing (to prevent any leakage between spaces 515, 525) since the gasket 620 has different properties (e.g., elasticity) than a hard surface (FIG. 10).

Notably, the figures and examples above are not meant to limit the scope of the present invention to a single embodiment, as other embodiments are possible by way of interchange of some or all of the described or illustrated elements. Moreover, where certain elements of the present invention can be partially or fully implemented using known components, only those portions of such known components that are necessary for an understanding of the present invention are described, and detailed descriptions of other portions of such known components are omitted so as not to obscure the invention. In the present specification, an embodiment showing a singular component should not necessarily be limited to other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

The foregoing description of the specific embodiments will so fully reveal the general nature of the invention that others can, by applying knowledge within the skill of the relevant art(s) (including the contents of the documents cited and incorporated by reference herein), readily modify and/or adapt for various applications such specific embodiments, without undue experimentation, without departing from the general concept of the present invention. Such adaptations and modifications are therefore intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one skilled in the relevant art(s).

While various embodiments of the present invention have been described above, it should be understood that they have been presented by way of example, and not limitation. It would be apparent to one skilled in the relevant art(s) that various changes in form and detail could be made therein without departing from the spirit and scope of the invention. Thus, the present invention should not be limited by any of the above-described exemplary embodiments, but should be defined only in accordance with the following claims and their equivalents.

What is claimed is:

1. A dispense arm device for controllably discharging a fluid onto a substrate comprising: a dispense head coupled to and contained within an arm portion of the dispense arm device, wherein the dispense head having a valve assembly that is configured to operate in: (1) a recirculation mode in which a dispense outlet formed in the dispense head is closed off and a recirculation path is opened for allowing heated chemistry that is delivered to the dispense head to be delivered back from the dispense head to a remote location; and (2) a dispense mode in which the dispense outlet is opened to allow heated chemistry to flow along a dispense path and be discharged from the dispense head and the recirculation path is closed off.

2. The dispense arm device of claim 1, further including an elongated thermocouple that has a first end that is in fluid communication with a first conduit that is configured to receive the heated chemistry from the chemical supply location and an opposing second end that protrudes from the dispense head.

3. The dispense arm device of claim 2, wherein the dispense head includes a first section and a second section which is detachably coupled to the first section with a fastener, the dispense outlet being formed in the first section and the first end of the thermocouple is disposed within the first section and passes completely through and beyond an end of the second section.

4. The dispense arm device of claim 1, wherein the dispense head has a valve cavity in which the valve assembly is disposed, the dispense outlet being in selective fluid communication with the valve cavity.

5. The dispense arm device of claim 4, wherein the valve assembly comprises a plunger valve having a main body with a rear flange at one end and a forward flange at another end with a shaft portion connecting the forward flange to the main body.

6. The dispense arm device of claim 5, wherein the valve cavity has a first section in which the forward flange is located and a second section in which the rear flange is located, the dispense outlet being in fluid communication with the first section.

7. The dispense arm device of claim 6, wherein in the recirculation mode, the forward flange closes off the dispense outlet and in the dispense mode, the forward flange is offset from the dispense outlet which is oriented along the shaft portion for receiving the heated chemistry.

8. The dispense arm device of claim 1, wherein the dispense head has defined therein a first pathway for receiving the heated chemistry and delivering the heated chemistry to a valve cavity in which the valve assembly is movably disposed, a second pathway that is in fluid communication with the valve cavity for receiving unused heated chemistry from the valve cavity, a third pathway for delivering working fluid to the valve cavity to act on the valve assembly, and a fourth pathway that is in fluid communication with the valve cavity for aspirating any unused heated chemistry therefrom, wherein in the recirculation mode, the first pathway and the second pathway are in fluid communication with one another and in the dispense mode, the first pathway and the dispense outlet are in fluid communication with one another.

9. The dispense arm device of claim 8, wherein the valve assembly comprises a plunger valve having a main body with a rear flange at one end and a forward flange at another end with a shaft portion connecting the forward flange to the main body and the valve cavity has a first section in which the forward flange is located and a second section in which the rear flange is located, the dispense outlet being in fluid communication with the first section, the third pathway being in fluid communication with the second section of the valve cavity, while the first pathway, second pathway and third pathway are in fluid communication with the first section.

10. The dispense arm device of claim 8, wherein in the dispense mode, the forward flange closes off the second pathway resulting in the first pathway being in fluid communication with the open dispense outlet and in the dispense mode, the heated chemistry can flow around the shaft portion from the first pathway to the dispense outlet, and in the recirculation mode, the heated chemistry can flow in front of the forward flange.

11. The dispense arm device of claim 1, wherein the valve assembly includes a biasing element that applies a return force to a plunger type valve body to return the plunger type valve body to a default position which comprise the recirculation mode.

12. The dispense arm device of claim 11, wherein when a force is applied to one end of the plunger type valve body, the return force is overcome and the plunger type body moves forward resulting in a recirculation pathway being closed and the dispense mode is in effect.

13. The dispense arm device of claim 11, further including a bellows disposed about the plunger type valve body and being surrounded by the biasing element.

14. The dispense arm device of claim 1, further including a valve seat, the valve assembly seating against the valve seat in the recirculation mode.

15. The dispense arm device of claim 14, wherein the valve seat comprises one of a flexible wall extending into the valve cavity, an O-ring, and a gasket.

16. The dispense arm device of claim 1, wherein the dispense head has defined therein a first pathway for receiving the heated chemistry and delivering the heated chemistry to a valve cavity in which the valve assembly is movably disposed, a second pathway that is in fluid communication with the valve cavity for receiving unused heated chemistry from the valve cavity, a third pathway for delivering working fluid to the valve cavity to act on the valve assembly, and a fourth pathway that is in fluid communication with the valve cavity for aspirating any unused heated chemistry therefrom, wherein in the recirculation mode, the first pathway and the second pathway are in fluid communication with one another and in the dispense mode, the first pathway and the dispense outlet are in fluid communication with one another; and
an elongated thermocouple that has a first end that is in fluid communication with the first pathway and an opposing second end that protrudes from the dispense head.

17. The dispense arm device of claim 8, wherein the first pathway includes a first tubular conduit that protrudes outwardly from one end of a main body of the dispense head; the second pathway includes a second tubular conduit that protrudes outwardly from the one end of the main body; the third pathway includes a third tubular conduit that protrudes outwardly from the one end of the main body; and the fourth pathway includes a fourth tubular conduit that protrudes outwardly from the one end of the main body.

18. The dispense arm device of claim 17, wherein the main body of the dispense head includes a first channel formed therein to which the first tubular conduit is in fluid communication; a second channel formed therein to which the second tubular conduit is in fluid communication; a third channel formed therein to which the third tubular conduit is in fluid communication; and a fourth channel formed therein to which the fourth tubular conduit is in fluid communication.

19. The dispense arm device of claim 1, wherein both the dispense path and the recirculation path share a common heated chemistry inlet pathway section for delivering the heated chemistry to the valve assembly.

20. The dispense arm device of claim 19, wherein the heated chemistry flows in front of one end of a valve member of the valve assembly in the recirculation mode and the valve member closes off the dispense outlet, while the heated chemistry flows around an intermediate portion of the valve member in the dispense mode and the valve member closes off a return recirculation pathway.

21. A method for operating a dispense arm device for controllably discharging a fluid onto a substrate comprising:
positioning a valve assembly that is located in a dispense head in a first position which is a recirculation mode of operation in which a dispense outlet formed in the dispense head is closed off and a recirculation path is opened for allowing heated chemistry that is delivered to the dispense head to be delivered back from the dispense head to a chemical recycle location without dispensing through the dispense outlet; and
when dispensing of the heated chemistry is required, positioning the valve assembly in a second position which is a dispense mode in which the dispense outlet is opened to allow the heated chemistry to flow along a dispense path and be discharged from the dispense head and the recirculation path is closed off.

22. The method of claim 21, wherein both the dispense path and the recirculation path share a common heated chemistry inlet pathway section for delivering the heated chemistry to the valve assembly.

23. The method of claim 22, wherein the heated chemistry flows in front of one end of a valve member of the valve assembly in the recirculation mode and the valve member closes off the dispense outlet, while the heated chemistry flows around an intermediate portion of the valve member in the dispense mode and the valve member closes off a return recirculation pathway.

24. The method of claim 21, further including the step of applying a force to one end of the valve assembly sufficient to overcome a biasing force applied to the valve assembly to move the valve assembly from a rest position which corresponds to the recirculation mode to an extended position which corresponds to the dispense mode.

25. The method of claim 21, further including the step of measuring a temperature of the heated chemistry at a location that is proximate to the valve assembly and is within an inlet conduit of the dispense pathway proximate to an entrance of the inlet conduit into a valve cavity in which the valve assembly is housed and prior to the heated chemistry being either dispensed through the dispense outlet or flowing within the recirculation pathway.
